(19) United States
(12) Patent Application Publication
(10) Pub. No.: US 2007/0289621 A1
(43) Pub. Date: Dec. 20, 2007

(54) ILLUMINATION SYSTEM

(75) Inventor: Yuma HORIO, Shizuoka-ken (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-Shi (JP)

(21) Appl. No.: 11/763,014

(22) Filed: Jun. 14, 2007

(30) Foreign Application Priority Data
Jun. 15, 2006 (JP) 2006-166492

(51) Int. Cl. H01L 35/30

(52) U.S. Cl. 136/205

(57) ABSTRACT

An illumination system includes an illumination unit and a thermoelectric conversion module. The illumination unit includes a light source, and a reflection plate capable of radiating heat from the light source to the outer circumference of the plate. The thermoelectric conversion module includes lower and upper substrates, lower and upper electrodes provided on the facing surfaces of the lower and upper substrates, and thermoelectric elements disposed between the lower and upper electrodes. The lower substrate of the thermoelectric conversion module is fixed to the reflection plate via a heat transfer member. The upper substrate of the thermoelectric conversion module is connected via a heat releasing path member to a support member (heat absorber) having a thermal conductivity higher than that of air.

### BACKGROUND OF THE INVENTION

1. Field of the Invention

The present invention relates to an illumination system, and more particularly to an illumination system which can generate electric power by utilizing heat from a light source.

2. Description of the Related Art

An illumination system of this type is disclosed in, for example, Japanese Patent Application Laid-Open (kokai) No. 2004-312986. The disclosed illumination system includes an illumination unit having a light source, and a reflection plate capable of radiating heat from the light source to the outer circumference of the plate; and a thermoelectric conversion module including a pair of insulators provided so as to face each other, electrodes provided at predetermined positions on the facing surfaces of the insulators, and thermoelectric elements whose end surfaces are bonded to the electrodes. In this illumination system, one of the paired insulators is provided on the outer circumference of the reflection plate, and electric power can be generated by utilizing heat transferred from one insulator (high-temperature-side insulator) to the other insulator (low-temperature-side insulator). The illumination system disclosed in the aforementioned publication is applied to a projector apparatus.

In the projector apparatus described in the aforementioned publication, a heat radiation fin is connected to the low-temperature-side insulator, and the temperature of the low-temperature-side insulator is maintained at a low level by increasing the amount of heat radiated from the heat radiation fin to air by means of air flow generated by a motor-driven cooling fan, whereby a predetermined temperature difference is maintained between these two insulators.

However, in the projector apparatus described in the aforementioned publication, electric power is consumed for driving the cooling fan. Therefore, the apparatus poses a problem in that a usable portion of the electric power generated by the thermoelectric conversion module decreases; i.e., the thus-generated electric power cannot be utilized with sufficient effectiveness.

### SUMMARY OF THE INVENTION

In order to cope with such a problem, an object of the present invention is to provide an illumination system comprising a thermoelectric conversion module having insulators, wherein a predetermined temperature difference can be maintained between the insulators without employment of a cooling fan.

In order to achieve the aforementioned object, the present invention provides an illumination system comprising an illumination unit including a light source, and a reflection plate capable of radiating heat from the light source to the outer circumference of the plate; and a thermoelectric conversion module including a pair of insulators provided so as to face each other, electrodes provided at predetermined positions on the facing surfaces of the insulators, and thermoelectric elements whose end surfaces are bonded to the electrodes, wherein one of the paired insulators (hereinafter may be referred to as the “first insulator”) is provided on the outer circumference of the reflection plate, and electric power is generated by utilizing heat transferred from the first insulator to the other insulator (hereinafter may be referred to as the “second insulator”). A characteristic feature of the illumination system resides in that the second insulator is connected in a heat conductable manner, via a member which forms a heat releasing path (hereinafter the member may be referred to as a “heat releasing path member”), to a heat absorber having a thermal conductivity higher than that of air. In this case, preferably, the heat absorber is, for example, a metallic support member installed in a building for supporting the illumination unit; flowing river water; lake water; sea water; or wet ground of a park or the like.

In the illumination system, heat from the light source is conducted through the reflection plate to the thermoelectric conversion module; the heat is conducted from the first insulator (high-temperature-side insulator) of the thermoelectric conversion module through the thermoelectric elements to the second insulator (low-temperature-side insulator); and the heat is conducted from the low-temperature-side insulator through the heat releasing path member to the heat absorber. Since the heat absorber has a thermal conductivity higher than that of air, heat is distributed in the heat absorber without being accumulated therein, and thus heat is always efficiently conducted from the heat releasing path member to the heat absorber. Therefore, even when a cooling fan is not employed, the temperature of the second insulator (low-temperature-side insulator) can be maintained at a low level, and a predetermined temperature difference can be maintained between the two insulators. Thus, since no cooling fan is required for maintaining a predetermined temperature difference between the two insulators, electric power generated by the thermoelectric conversion module can be utilized with sufficient effectiveness.

In the present invention, the heat releasing path member may be made of aluminum or an aluminum alloy. In this case, the weight of the illumination system can be reduced while increasing efficiency of heat conduction from the thermoelectric conversion module to the heat absorber.

In the present invention, a heat transfer member may be provided between the first insulator and the outer circumferential surface of the reflection plate. In this case, heat can be efficiently conducted from the reflection plate of the illumination unit to the thermoelectric conversion module.

In the present invention, the heat transfer member may have a horizontal surface generally perpendicular to the vertical direction, and the first insulator may be provided on the horizontal surface. In this case, by virtue of the property of heat (i.e., heat generally transfers upward), heat can be effectively conducted from the reflection plate through the heat transfer member to the thermoelectric conversion module.

In the present invention, the heat transfer member may be made of aluminum or an aluminum alloy. In this case, the weight of the illumination system can be reduced while increasing efficiency of heat conduction through the heat transfer member.

In the present invention, at least a portion of the outer circumferential surface of the reflection plate, which surface is exposed to air, may be coated with a heat insulation material; or at least a portion of the outer surface of the heat transfer member, which surface is exposed to air, may be coated with a heat insulation material. Alternatively, the air-exposed outer circumferential surface of the reflection plate and the air-exposed outer surface of the heat transfer member may be coated with a heat insulation material. In this case, for example, the area of a region coated with the heat insulation material is 50% or more, preferably 80% or more, the total area of the outer circumferential surface of the reflection plate and the outer surface of the heat transfer member.

In this case, since the amount of heat radiated from the outer circumferential surface of the reflection plate and the outer surface of the heat transfer member to air is reduced by means of the heat insulation material, the amount of heat which passes through the thermoelectric conversion module can be increased. Therefore, electric power generation efficiency of the thermoelectric conversion module can be increased.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic representation showing an indoor downlight illumination system according to a first embodiment of the illumination system of the present invention;

FIG. 2 is a perspective view of the thermoelectric conversion module shown in FIG. 1;

FIG. 3 is a front view of the thermoelectric conversion module shown in FIG. 1;

FIG. 4 is a partially cross-sectional view of the illumination system of FIG. 1, as taken along line 4-4;

FIG. 5 is a partially cross-sectional view corresponding to that of FIG. 4 and showing a modification of the first embodiment;

FIG. 6 is a schematic representation showing an outdoor nighttime illumination system according to a second embodiment of the illumination system of the present invention; and

FIG. 7 is a partially cross-sectional front view showing the state where the illumination unit shown in FIG. 6 is attached to a railing.

### DETAILED DESCRIPTION OF PREFERRED EMBODIMENTS

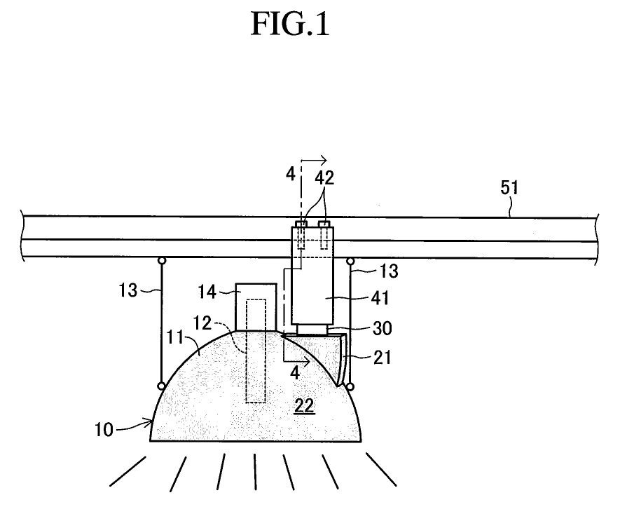

Embodiments of the present invention will next be described with reference to the drawings. FIG. 1 shows an indoor downlight illumination system according to a first embodiment of the illumination system of the present invention. The indoor downlight illumination system includes an illumination unit 10, a heat transfer member 21, a thermoelectric conversion module 30, a heat releasing path member 41, and a support member 51.

The illumination unit 10 includes a reflection plate 11 and an electric bulb 12 (light source). The reflection plate 11 has a generally dome-like shape and is made of aluminum. The reflection plate 11 is supported by the support member 51 via attachment members 13 provided on the outer circumferential surface of the plate 11. The inner circumferential surface of the reflection plate 11 is coated with a reflective film (e.g., aluminum deposition film), and light from the electric bulb 12 is reflected downward by the reflective film.

The electric bulb 12 is located generally at the center of the interior of the reflection plate 11, and is attached to a socket 14 at the back of the center of the reflection plate 11 in such a manner that electricity can be supplied to the electric bulb 12. The attachment members 13 are formed of, for example, ceramic chains having low thermal conductivity, and are provided between the reflection plate 11 and the support member 51 so that a predetermined tensile force is applied to the members 13.

The heat transfer member 21, which is formed of an aluminum block, has a horizontal top surface generally perpendicular to the vertical direction, and a bottom surface which curbs along the outer circumferential surface of the reflection plate 11. The bottom surface of the heat transfer member 21 is fixed to the reflection plate 11 such that the member 21 and the plate 11 are united together. The outer surface of the heat transfer member 21 and the outer circumferential surface of the reflection plate 11, which surfaces are exposed to air, are coated with a heat insulation material 22.

The heat insulation material 22 is, for example, a coating material capable of forming a ceramic coating film exhibiting low thermal conductivity. The heat insulation material 22 is applied to the reflection plate 11 and the heat transfer member 21 so that the area of a region coated with the material 22 is about 80% the total area of the air-exposed outer circumferential surface of the plate 11 and the air-exposed outer surface (exclusive of the top surface) of the member 21. The greater the area of a region coated with the heat insulation material 22, the smaller the amount of heat radiated from the reflection plate 11 and the heat transfer member 21 to air. However, the thus-accumulated heat may adversely affect durability of the electric bulb 12. Therefore, the coating area is determined as described above, so as to suppress radiation of heat to air and to maintain durability of the electric bulb 12.

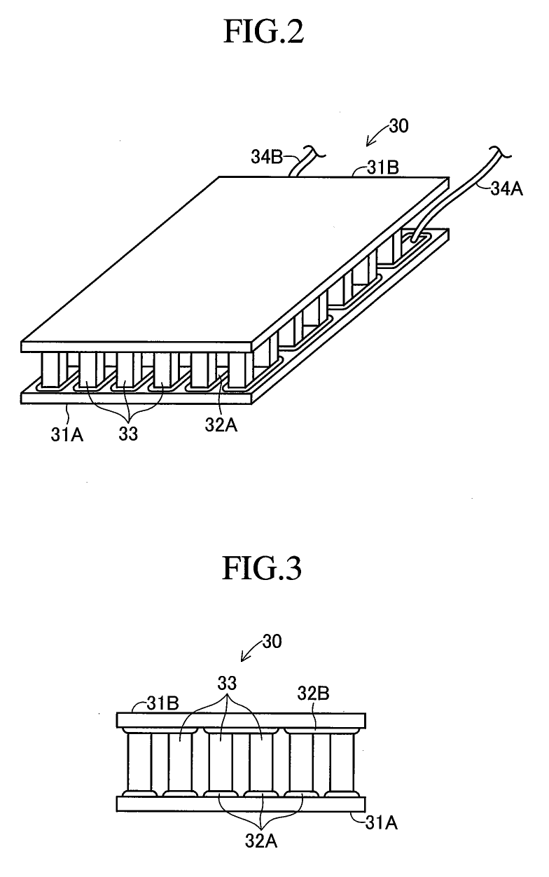

As shown in FIGS. 2 and 3, the thermoelectric conversion module 30 includes a lower substrate 31A; an upper substrate 31B; lower electrodes 32A; upper electrodes 32B; and thermoelectric elements 33, the lower substrate 31A and the upper substrate 31B being a pair of insulators. The lower substrate 31A and the upper substrate 31B are formed from alumina into a predetermined rectangular plate shape. The bottom surface of the lower substrate 31A is fixed to the top surface of the heat transfer member 21, and the top surface of the upper substrate 31B is fixed to the bottom surface of the heat releasing path member 41 (see FIG. 1). By means of tensile force applied to the attachment members 13, the thermoelectric conversion module 30 is fixed so that no gap is formed between the bottom surface of the lower substrate 31A and the top surface of the heat transfer member 21, and between the top surface of the upper substrate 31B and the bottom surface of the heat releasing path member 41.

Each of the lower electrodes 32A and the upper electrodes 32B has such a size that end surfaces of two thermoelectric elements 33 can be bonded thereto. The lower electrodes 32A are attached to the top surface of the lower substrate 31A at predetermined positions, and the upper electrodes 32B are attached to the bottom surface of the upper substrate 31B at predetermined positions. The lower electrodes 32A and the upper electrodes 32B are provided in a staggered fashion such that they are shifted form one another by a distance generally equal to the size of one thermoelectric element 33 in the longitudinal direction of the lower substrate 31A and the upper substrate 31B (i.e., in a forward-backward direction as viewed in FIG. 2). Lead wires 34A and 34B are attached to the lower electrodes 32A provided at two corners of the lower substrate 31A so that the electrodes can be electrically connected to an external device or the like.

The thermoelectric elements 33, which assume a rectangular parallelepiped shape, are formed of P-type and N-type elements made of, for example, a bismuth-tellurium alloy. The P-type and N-type thermoelectric elements 33 are alternately provided in left-right and forward-backward directions as viewed in FIG. 2. The bottom surfaces of the elements 33 are fixed to the top surfaces of the lower electrodes 32A, and the top surfaces of the elements 33 are fixed to the bottom surfaces of the upper electrodes 32B. All the thermoelectric elements 33 are connected in series between the lower substrate 31A and the upper substrate 31B via the lower electrodes 32A and the upper electrodes 32B.

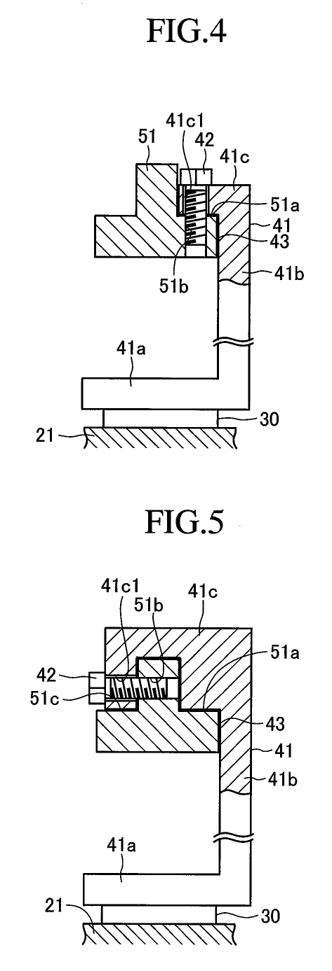

As shown in FIG. 4, the heat releasing path member 41, which is made of aluminum, has a generally L-shaped vertical cross section, and is provided between the heat transfer member 21 and the support member 51. The heat releasing path member 41 includes a substrate-engaging section 41a which extends in a horizontal direction; a connection section 41b which extends upward from one end of the substrate-engaging section 41a in the vertical direction; and a support-member-engaging section 41c which extends from the upper end of the connection section 41b in a horizontal direction.

The bottom surface of the substrate-engaging section 41a is fixed to the top surface of the upper substrate 31B of the thermoelectric conversion module 30. The substrate-engaging section 41a is formed such that the bottom surface thereof has an area somewhat larger than that of the top surface of the upper substrate 31B. The connection section 41b has such a size that it has at least a predetermined cross-sectional area so as to reduce its thermal resistance to a predetermined level or less. The support-member-engaging section 41c has a through-hole 41c1 into which a bolt 42 can be inserted in the vertical direction.

As shown by thick solid lines in FIG. 4, heat-radiating grease 43 is applied to the engagement surface between the support-member-engaging section 41c and the support member 51 and to the engagement surface between the connection section 41b and the support member 51 so that no gap is formed at these engagement surfaces. The heat-radiating grease 43 is made of, for example, silicon, which exhibits high thermal durability and high thermal conductivity. The heat-radiating grease 43 plays a role in reducing thermal resistance and in increasing thermal conduction from the heat releasing path member 41 to the support member 51.

The support member 51 (heat absorber), which supports the illumination unit 10, is formed of an iron rod, and is mounted to a building structure (not illustrated). The support member 51 has an inverted T-shaped cross section such that a predetermined surface area can be attained, and a step section 51a of the support member 51 has a screw hole 51b which penetrates therethrough in the vertical direction. When the bolt 42 is screwed into the screw hole 51b, with the support-member-engaging section 41c being engaged with the step section 51a, the heat releasing path member 41 is united with the support member 51.

In the indoor downlight illumination system according to the first embodiment, which has the aforementioned configuration, heat from the electric bulb 12 of the illumination unit 10 is conducted through the reflection plate 11 to the thermoelectric conversion module 30. Subsequently, heat is conducted, through the lower substrate 31A (on the high-temperature side) of the thermoelectric conversion module 30, the lower electrodes 32A, the thermoelectric elements 33, and the upper electrodes 32B, to the upper substrate 31B (on the low-temperature side), and then heat is conducted through the heat releasing path member 41 to the support member 51.

Iron constituting the support member 51 has a thermal conductivity at room temperature (300 K) of about 80.3 W/(m·K), which is considerably higher than the thermal conductivity of air (i.e., about 0.026 W/(m·K)). Therefore, heat is distributed in the support member 51 without being accumulated therein, and is radiated through the outer surface of the support member 51 and the outer surface of the building structure, and thus heat is always efficiently conducted from the heat releasing path member 41 to the support member 51.

With this configuration, even when a cooling fan is not employed, the temperature of the upper substrate 31B of the thermoelectric conversion module 30 can be maintained at a low level, and a predetermined temperature difference can be maintained between the substrates 31A and 31B. Therefore, since no cooling fan is required for maintaining a predetermined temperature difference between the substrates 31A and 31B, electric power generated by the thermoelectric conversion module 30 can be utilized with sufficient effectiveness. This configuration, which does not require installation of a cooling fan or a like device on the ceiling, is also advantageous in that maintenance for such an apparatus is not required.

In the first embodiment, the heat releasing path member 41 is made of aluminum. Since aluminum has a thermal conductivity of about 236 W/(m·K), which is considerably higher than that of air, the heat releasing path member 41 can efficiently conduct heat transferred to the upper substrate 31B to the support member 51. In addition, the weight of the heat releasing path member 41 can be reduced, and thus the total weight of the illumination system can be reduced.

In the first embodiment, the top surface of the heat transfer member 21 is a horizontal surface generally perpendicular to the vertical direction, and the top surface is in almost close contact with the lower substrate 31A of the thermoelectric conversion module 30. Therefore, by virtue of the property of heat (i.e., heat generally transfers upward), heat can be effectively conducted from the heat transfer member 21 to the lower substrate 31A of the thermoelectric conversion module 30.

In the first embodiment, the heat transfer member 21 is made of aluminum. Therefore, the heat transfer member 21 can efficiently conduct heat from the reflection plate 11 to the lower substrate 31A of the thermoelectric conversion module 30. In addition, the weight of the heat transfer member 21 can be reduced, and thus the total weight of the illumination system can be reduced.

In the first embodiment, the outer surface of the heat transfer member 21 and the outer circumferential surface of the reflection plate 11, which surfaces are exposed to air, are coated with the heat insulation material 22, and the heat insulation material 22 is applied to the reflection plate 11 and the heat transfer member 21 so that the area of a region coated with the material 22 is about 80% the total area of the air-exposed outer circumferential surface of the plate 11 and the air-exposed outer surface (exclusive of the top surface) of the member 21. Therefore, the amount of heat radiated through the outer circumferential surface of the reflection plate 11 and the outer surface of the heat transfer member 21 to air is reduced, and the amount of heat which passes through the thermoelectric conversion module 30 is increased, whereby electric power generation efficiency of the thermoelectric conversion module 30 can be increased.

In the first embodiment, as shown in FIG. 4, the support-member-engaging section 41c of the heat releasing path member 41 is formed to have such a shape that it can be engaged with the step section 51a of the support member 51. However, for example, as shown in FIG. 5, the support-member-engaging section 41c of the heat releasing path member 41 may be formed to have such a shape that it extends over the top of the support member 51 and can be engaged not only with the step section 51a on one side but also with another step section 51c on the other side. In this modification of the first embodiment, components other than the heat releasing path member 41 are similar to those described above in the first embodiment. Therefore, the same members as those employed in the first embodiment, or members having the same function as those employed in the first embodiment are denoted by common reference numerals, and repeated description thereof is omitted.

According to this modification, since the area of engagement of the support member 51 with the support-member-engaging section 41c of the heat releasing path member 41 is increased, as compared with the case of the first embodiment, heat is further efficiently conducted from the heat releasing path member 41 to the support member 51, and thus a predetermined temperature difference can be readily maintained between the substrates 31A and 31B.

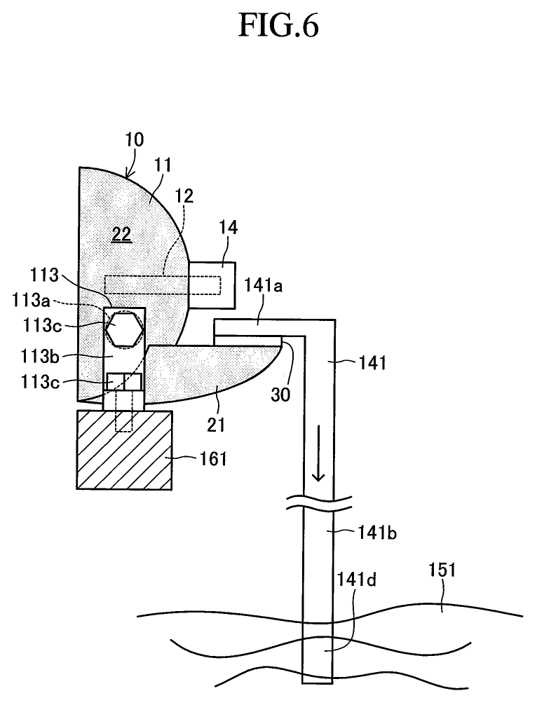

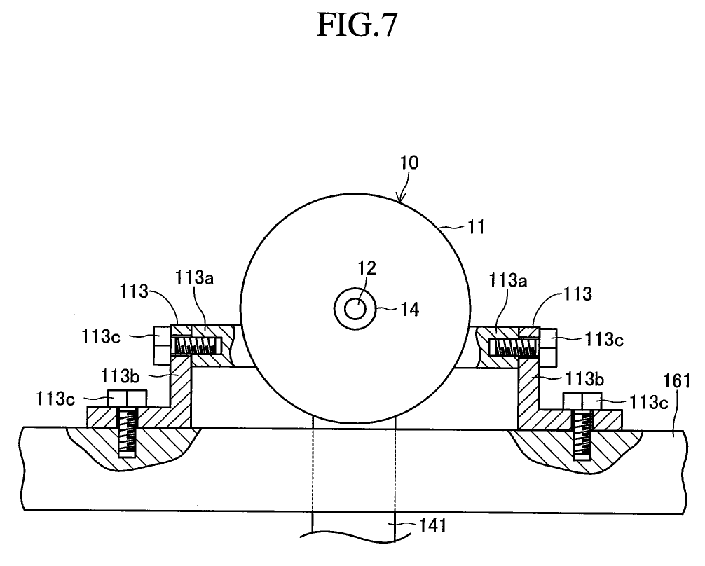

In the first embodiment and the modification thereof (hereinafter may be referred to as “the first embodiment, etc.”), the illumination system of the present invention is applied to an indoor downlight illumination system. However, the present invention is not necessarily limited thereto, and, for example, as shown in FIGS. 6 and 7, the illumination system of the present invention may be applied to an outdoor nighttime illumination system (second embodiment). The second embodiment will be described by focusing on components different from those employed in the first embodiment, etc. Therefore, the same components as those employed in the first embodiment, etc., or components having the same function as those employed in the first embodiment, etc. are denoted by common reference numerals, and repeated description is omitted.

The outdoor nighttime illumination system includes an illumination unit 10 which is attached to a railing 161 via an attachment member 113. The illumination unit 10 includes a reflection plate 11 which is in contact, via a heat transfer member 21, a thermoelectric conversion module 30, and a heat releasing path member 141, with flowing river water 151. The attachment member 113 includes a nut 113a, a bracket 113b, and a bolt 113c. The bracket 113b is made of, for example, ceramic material having low thermal conductivity so that when the reflection plate 11 of the illumination unit 10 is attached via the bracket 113b to the railing 161, heat does not easily move from the reflection plate 11 to the railing 161.

The heat releasing path member 141 is formed of a generally L-shaped aluminum rod. The heat releasing path member 141 includes a substrate-engaging section 141a which extends in a horizontal direction, and a connection section 141b which extends downward from one end of the substrate-engaging section 141a in the vertical direction. A lower end portion of the connection section 141b serves as a water-contacting section 141d which is in contact with the flowing river water 151 (heat absorber). The connection section 141b has such a size that it has at least a predetermined cross-sectional area (e.g., a square cross section having a size of 30 mm×30 mm) so as to reduce its electric resistance to a predetermined level or less.

In the nighttime illumination system according to the second embodiment, which has the aforementioned configuration, heat conducted from the reflection plate 11 of the illumination unit 10 to the thermoelectric conversion module 30 is transferred through the heat releasing path member 141 to the flowing river water 151.

Water has a thermal conductivity of about 0.6 W/(m·K), and, in general, the temperature of river water is lower than air temperature. Therefore, heat is distributed in the flowing river water 151 without being accumulated therein, and thus heat is always efficiently conducted from the heat releasing path member 141 to the flowing water river 151. With this configuration, similar to the case of the first embodiment, etc., even when a cooling fan is not employed, a predetermined temperature difference can be maintained between the substrates 31A and 31B of the thermoelectric conversion module 30, and electric power generated by the thermoelectric conversion module 30 can be utilized with sufficient effectiveness.

In the second embodiment, similar to the case of the first embodiment, etc., the weight of the heat releasing path member 141 can be reduced, and thus the total weight of the illumination system can be reduced. In addition, since the air-exposed outer surface of the heat transfer member 21 and the air-exposed outer circumferential surface of the reflection plate 11 are coated with a heat insulation material 22, electric power generation efficiency of the thermoelectric conversion module 30 can be increased.

### EXAMPLES

Specific examples of the aforementioned embodiments will next be described. In each of the examples, generated electric power was measured.

### Example 1

In Example 1, the present invention was applied to a downlight illumination instrument in the interior of a shop. In Example 1, the electric bulb 12 of the illumination unit 10 was a 180 W incandescent lamp. The size of the thermoelectric conversion module 30 was determined to be 35 mm×35 mm×3.5 mm, and 190 pairs of the P-type and N-type thermoelectric elements 33 made of a bismuth-tellurium alloy were employed. The area of the top surface of the heat transfer member 21 was determined to be 14 cm², and the volume of the heat transfer member 21 was determined to be 30 cm³. The air-exposed outer circumferential surface of the reflection plate 11 and the air-exposed outer surface (exclusive of the top surface) of the heat transfer member 21 were coated with a ceramic coating film (i.e., the heat insulation material 22) so that the area of a region coated with the material 22 accounted for about 80% of the total area of these outer surfaces. When the temperature of the lower substrate 31A (on the high-temperature side) was 130° C., and the temperature of the upper substrate 31B (on the low-temperature side) was 45° C.; i.e., when the temperature difference between the substrates 31A and 31B was 85 degrees in Celsius, an electric power of 4.4 W was generated. The thus-generated electric power was charged in a storage battery, and was used as electric power for another illumination instrument intermittently used in the shop.

### Example 2

In Example 2, similar to the case of Example 1, the present invention was applied to a downlight illumination instrument in the interior of a shop. In Example 2, the electric bulb 12 of the illumination unit 10 was a 150 W incandescent lamp. The size of the thermoelectric conversion module 30 was determined to be 28 mm×28 mm×3 mm, and 127 pairs of the P-type and N-type thermoelectric elements 33 made of a bismuth-tellurium alloy were employed. The area of the top surface of the heat transfer member 21 was determined to be 10.5 cm², and the volume of the heat transfer member 21 was determined to be 21 cm³. The air-exposed outer circumferential surface of the reflection plate 11 and the air-exposed outer surface (exclusive of the top surface) of the heat transfer member 21 were coated with a ceramic coating film (i.e., the heat insulation material 22) so that the area of a region coated with the material 22 accounted for about 80% of the total area of these outer surfaces. When the temperature of the lower substrate 31A (on the high-temperature side) was 120° C., and the temperature of the upper substrate 31B (on the low-temperature side) was 40° C.; i.e., when the temperature difference between the substrates 31A and 31B was 80 degrees in Celsius, an electric power of 3.8 W was generated. The thus-generated electric power was employed as electric power for a drive motor of an electrically driven small fan for advertisement.

### Example 3

In Example 3, the present invention was applied to a nighttime illumination instrument provided on a railing of a bridge spanning a river. In Example 3, the electric bulb 12 of the illumination unit 10 was a 200 W incandescent lamp. The size of the thermoelectric conversion module 30 was determined to 40 mm×40 mm×3.3 mm, and 98 pairs of the P-type and N-type thermoelectric elements 33 made of a bismuth-tellurium alloy were employed. The area of the top surface of the heat transfer member 21 was determined to be 18 cm², and the volume of the heat transfer member 21 was determined to be 36 cm³. The air-exposed outer circumferential surface of the reflection plate 11 and the air-exposed outer surface (exclusive of the top surface) of the heat transfer member 21 were coated with a ceramic coating film (i.e., the heat insulation material 22) so that the area of a region coated with the material 22 accounted for about 60% of the total area of these outer surfaces. When the temperature of the lower substrate 31A (on the high-temperature side) was 110° C., and the temperature of the upper substrate 31B (on the low-temperature side) was 20° C.; i.e., when the temperature difference between the substrates 31A and 31B was 90 degrees in Celsius, an electric power of 5.2 W was generated. Ten sets of such illumination instruments were provided, and the thus-generated electric power was charged in a storage battery. The electric power was used for driving a music player during the day, or employed as electric power for another type of an illumination instrument.

In Example 3, temperature of the lower substrate 31A (on the high-temperature side) of the thermoelectric conversion module 30 was measured with varying the area of a region coated with the heat insulation material 22. The results are shown in Table 1.

TABLE 1

| | | | | | |
|---|---|---|---|---|---|
| Heat insulation material | 0% | 30% | 50% | 80% | 100% |
| coating area ratio | | | | | |
| Module high- | 74° C. | 85° C. | 110° C. | 130° C. | 146° C. |
| temperature-side | | | | | |
| temperature | | | | | |

As used herein, the expression “heat insulation material coating area ratio” refers to the ratio of the area of a region coated with the heat insulation material 22 to the total area of the air-exposed outer circumferential surface of the reflection plate 11 and the air-exposed outer surface (exclusive of the top surface) of the heat transfer member 21. As shown in Table 1, when the heat insulation material coating area ratio is 50% or more, a desired temperature difference is attained between the substrates 31A and 31B.

In the aforementioned embodiments, the ratio of the area of a region coated with the heat insulation material to the total area of the air-exposed outer circumferential surface of the reflection plate 11 and the air-exposed outer surface (exclusive of the top surface) of the heat transfer member 21; i.e., the heat insulation material coating area ratio, is determined to be 80%. However, as is clear from Table 1, the heat insulation material coating area ratio may be appropriately changed so as to fall within a range of 50% or more and less than 80%. When durability of the electric bulb 12 is well maintained, the heat insulation material coating area ratio may be appropriately changed so as to fall within a range of 80% or more and 100% or less.

In the aforementioned embodiments, the heat insulation material 22 employed is a ceramic-containing coating material having low thermal conductivity. However, the heat insulation material 22 is not necessarily limited to such a coating material, and may be a heat insulation material such as glass fiber, felt, or plastic foam.

In the aforementioned embodiments, the heat transfer member 21 or the heat releasing path member 41 or 141 is made of aluminum. However, such a member is not necessarily made of aluminum, and may be made of, for example, a metal such as an aluminum alloy or copper.

In the aforementioned embodiments, the illumination system employs a single heat transfer member 21, a single thermoelectric conversion module 30, and a single heat releasing path member 41 or 141. However, the illumination system may employ a plurality of sets, each including the heat transfer member, thermoelectric conversion module, and heat releasing path member.

In the first embodiment, the attachment member 13 is formed of a ceramic chain, and, in the second embodiment, the attachment member 113 is formed by making use of the ceramic bracket 113b. However, the attachment member 13 or 113 may be formed of a variety of materials, so long as heat is not easily conducted from the reflection plate 11 through the attachment member 13 or 113.

In the second embodiment, the top surface of the heat transfer member 21 is a horizontal surface generally perpendicular to the vertical direction, and the top surface is in almost close contact with the lower substrate 31A of the thermoelectric conversion module 30. However, the heat transfer member may be formed to have a horizontal bottom surface generally perpendicular to the vertical direction, and the thermoelectric conversion module may be provided so that the upper substrate of the module is in almost close contact with the bottom surface of the heat transfer member. In this case, a voltage of reverse polarity is generated.

The illumination system of the present invention is not limited to the aforementioned embodiments, and may be applied to, for example, an illumination instrument installed at seashore, lakeshore, park, etc., or a light of an automobile, a motorcycle, or the like.

What is claimed is:

1. An illumination system comprising:
an illumination unit including a light source, and a reflection plate capable of radiating heat from the light source to the outer circumference of the plate;
a thermoelectric conversion module including a pair of insulators provided so as to face each other, electrodes provided at predetermined positions on facing surfaces of the insulators, and thermoelectric elements whose end surfaces are bonded to the electrodes, wherein a first insulator of the paired insulators is provided on the outer circumference of the reflection plate; and
a heat releasing path member through which a second insulator of the paired insulators is connected in a heat conductable manner to a heat absorber having a thermal conductivity higher than that of air, wherein
electric power is generated by utilizing heat transferred from the first insulator to the second insulator.

2. An illumination system according to claim 1, wherein the heat absorber is a metallic support member installed in a building for supporting the illumination unit.

3. An illumination system according to claim 1, wherein the heat absorber is flowing river water, lake water, or sea water.

4. An illumination system according to claim 1, wherein the heat releasing path member is made of aluminum or an aluminum alloy.

5. An illumination system according to claim 1, wherein a heat transfer member is provided between the first insulator and an outer circumferential surface of the reflection plate.

6. An illumination system according to claim 5, wherein the heat transfer member has a horizontal surface generally perpendicular to the vertical direction, and the first insulator is provided on the horizontal surface.

7. An illumination system according to claim 5, wherein the heat transfer member is made of aluminum or an aluminum alloy.

8. An illumination system according to claim 1, wherein at least a portion of an outer circumferential surface of the reflection plate, which surface is exposed to air, is be coated with a heat insulation material.

9. An illumination system according to claim 5, wherein at least a portion of an outer surface of the heat transfer member, which surface is exposed to air, is coated with a heat insulation material.

10. An illumination system according to claim 5, wherein the outer circumferential surface of the reflection plate, which surface is exposed to air, and the outer surface of the heat transfer member, which surface is exposed to air, are coated with a heat insulation material.

11. An illumination system according to claim 8, wherein the area of a region coated with the heat insulation material is 50% or more, preferably 80% or more, the total area of the outer circumferential surface of the reflection plate and the outer surface of the heat transfer member.

12. An illumination system according to claim 9, wherein the area of a region coated with the heat insulation material is 50% or more, preferably 80% or more, the total area of the outer circumferential surface of the reflection plate and the outer surface of the heat transfer member.

13. An illumination system according to claim 10, wherein the area of a region coated with the heat insulation material is 50% or more, preferably 80% or more, the total area of the outer circumferential surface of the reflection plate and the outer surface of the heat transfer member.
